(19) United States
(12) Patent Application Publication
(10) Pub. No.: US 2020/0049750 A1
(43) Pub. Date: Feb. 13, 2020

(54) Mach-Jansson Field Detector

(71) Applicant: Peter Mark Jansson, Lewisburg, PA (US)

(72) Inventor: Peter Mark Jansson, Lewisburg, PA (US)

(21) Appl. No.: 15/823,294

(22) Filed: Nov. 27, 2017

(51) Int. Cl. G01R 29/08

(52) U.S. Cl. CPC G01R 29/0864

(57) ABSTRACT

A device provides an electromagnetically active area where the presence of a newly discovered field can manifest its characteristic behavior. This detection area is comprised of electrochemical batteries, rarified inert gases and materials combined so as to be responsive to electromagnetic field changes with remote data transmission for collection. The device creates an inertial reaction effect from the field by creating a high inertial mass. When the inertia of the core is at a high level, the device can also provide a progressive rotation and other physical changes in the device's location in space. Observation of the electro-magnetically active detection area, which surrounds the core as a spherical surface, will reveal the newly observed Machian phenomenon. The observation will occur with a frequency equal or greater than the actual surface area where the detection material is active.

### BACKGROUND OF THE INVENTION

### 1. Field of the Invention

The present invention relates generally to field sensors and more particularly to electromagnetic field sensors.

### 2. Description of the Related Art

None at this time

### SUMMARY OF INVENTION

The present invention uses high inertia mass(es) to create the possibility of a large (high) inertial reaction force. Firstly the device creates a high-inertia rotational mass as its core operation. Second, the device provides a means or mechanism for creating motion in space of the inertial mass core when it is at high speed (rotational, translational, etc.) Third, the device provides an electromagnetically sensitive detection area comprised of e-m sensitive materials, e-m sensors, rechargeable batteries, e-m or e-s sensitive inert gases, coils, capacitors, or other chemical substances whereby the reaction force can be observed visibly or via other sensor readings (distributed volt-meters, sensors, etc.) when the disruption to the motion of the high inertia mass is precipitated, or in the case of large celestial alignments of nearby matter (sun, Moon, Virgo supercluster, etc.) with the earth and device, these regular small observations can be made with the device whether high inertia mass is disturbed or not (i.e., can be observed from inertia run up and run down alone).

The current embodiment of the device employs 10 small DC voltmeters and these devices read the voltages across the six (6) 1.2V AA rechargeable nickel cadmium battery series strings on each arm—labeled A through H) while remotely transmitting voltage change in the batteries to nearby collection unit. In total 48 AA batteries are used as sensors in this current detector and 4 AA batteries are used to drive the DC pancake motors that are able to create the rotational disturbance to the inertia of the central core of the device.

The batteries serving as the electromagnetically active detection area which fulfill the dual purpose of powering the central DC motors that keep the internal inertial mass rotating in excess of 6,000 rpm or desired rpm, while also responsive to the Machian-like reaction force when a disturbance in the local, high inertia mass is attempted. In previous experiments and smaller embodiments of the device the inventor was able to create instantaneous battery polarity reversal when the Machian field was interacted with in the proximity of the battery/sensor detectors. In order for the effect to manifest the other requirement is that the high inertia device is disturbed in its gyroscopic-like behavior. This can be achieved by hanging the device and altering its position in space via impact, rotation, or movement either internally or externally. Initial devices were rotated externally by the use of rubberized cords. The current device uses DC pancake motor drives connected to the top and bottom of the central inertial core.

### BRIEF DESCRIPTION OF THE DRAWINGS

For a more complete understanding of the invention, reference is made to the following detailed description in conjunction with the accompanying drawings, in which:

FIG. 1 is a top plan view of a sensor constructed in accordance with an embodiment of the present invention;

FIG. 2 is a cross-sectional view of the sensor shown in FIG. 1 taken along line A-A; and

FIG. 3 is a diagram of the electrical connections between the battery packs of the sensor shown in FIG. 1.

### DETAILED DESCRIPTION OF THE PREFERRED EMBODIMENTS

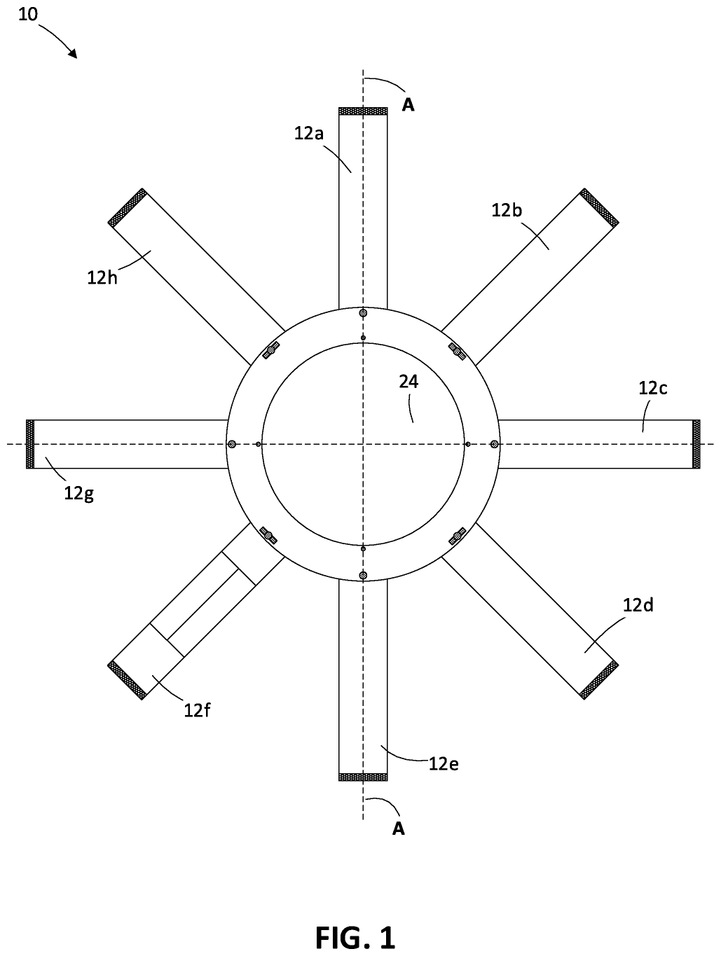

The device acts as a battery system sensor network that monitors and interacts with a Machian inertial reaction field/force while simultaneously creating a discernible transient mass fluctuation and large battery voltage disruption believed to be electromagnetic in nature. The device design is on a spherical shape to interact more effectively with the Machian inertial reaction field/force. The batteries on the 8 arms function both as power supply and sensors by having the batteries in optimum juxtaposition/proximity to the Machian interaction field induced by the challenges to the inertia of the wheel located at the center of the device. FIG. 1 provides a Plan view of the Detector illustrating the arrangement of the eight (8) battery/detector arms—spaced 45 degrees apart. In addition, the top DC pancake motor is attached to the upper supporting ring (shown) while the bottom motor and ring are obscured in this view.

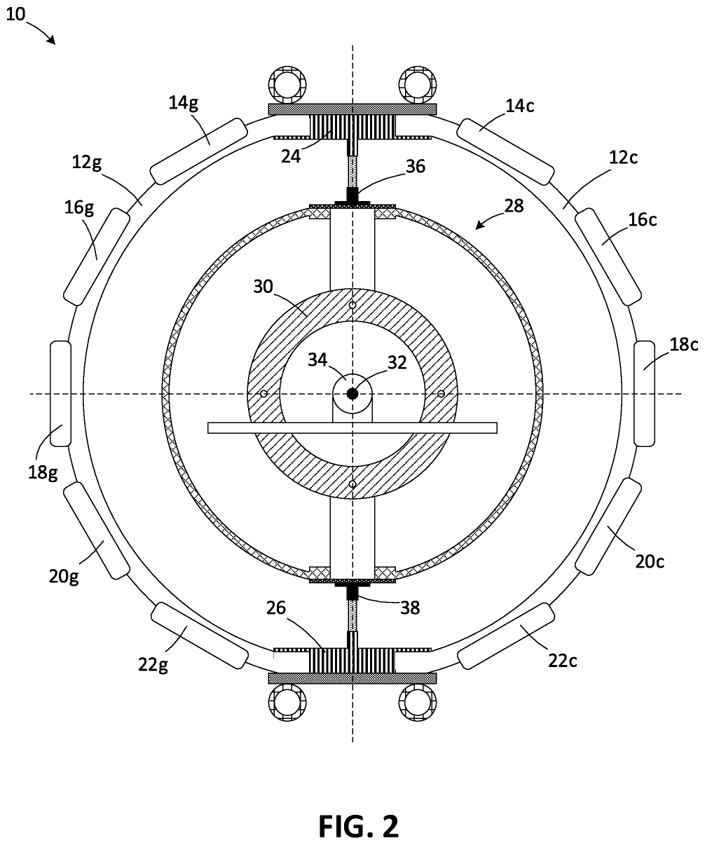

The device Elevation view (FIG. 2) is taken from a central cross-section to allow the visualization of all of the key components of the preferred embodiment. The central inertia wheel is supported on bearings, powered by DC motor(s) that are supported on a central aluminum platform. In this view, two (2) of the devices' eight (8) curved armatures are illustrated. These contain five (5) dual 1.2V AA battery packs each, three (3) normally powering the DC electric bus that powers the motors. Each of these batteries also acts as a “battery system sensor network” that monitors and interacts with a Machian inertial reaction field/force. The location of both the upper and lower DC pancake motor drives that are capable of providing constant torque to the system are shown in this view. The structural support rings that can be used to arrange the detector in a preferred orientation (given location of Earth and celestial bodies under observation) are shown, there are four (4) provided on each end of the detector.

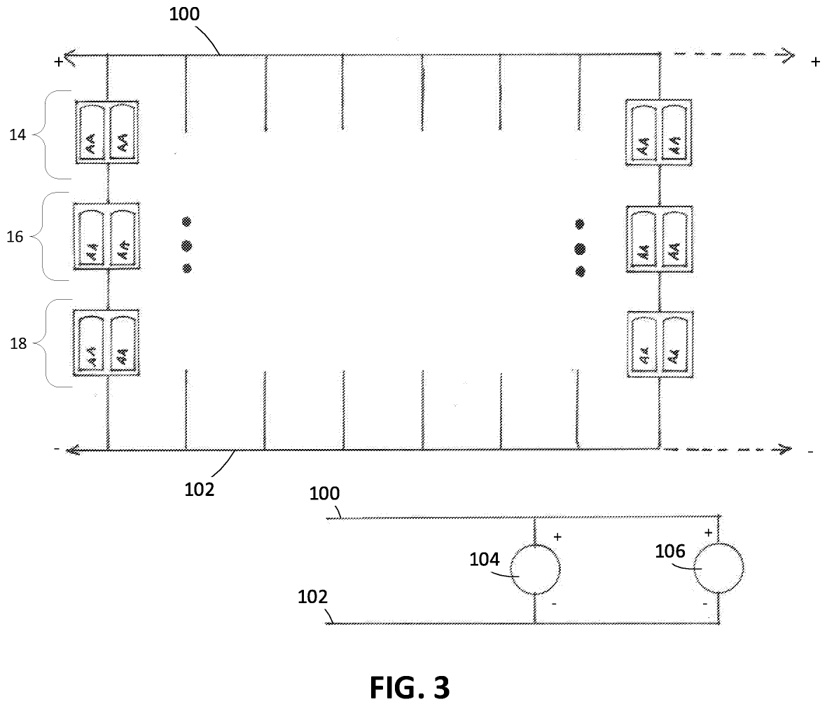

The device's simple electrical connections are shown in these views (FIG. 3) as was previously described the preferred embodiment uses 48 batteries in the DC array. This is comprised of eight (8) parallel strings of six (6) 1.2V AA batteries (connected in series) as shown in FIG. 3. The two (2) DC motors that power the central inertia wheel during the experimental protocol are connected to the DC bus in a parallel configuration.

Referring to FIGS. 1 and 2, the device consists of a −35 cm diameter open sphere 10 comprised of eight armatures 12a-h supporting the battery packs (i.e., battery rings 14, 16, 18, 20, 22), wiring and voltage sensors (not shown). Each of the arms 12a-h is spaced 45 degrees apart, with five (5) double battery holders to connected in series (see, e.g. battery packs 14c, 16c, 18c, 20c, 22c and battery packs 14g, 16g, 18g, 20g, 22g in FIG. 2). On the top and bottom of the sphere 10 are DC pancake motors 24, 26 attached to the central wheel assembly 28.

The central wheel assembly 28 consists of a central inertia wheel 30 six inches in diameter comprised of three laminated quarter inch aluminum discs with the central disc of a full six inches with the other two discs placed on opposite sides of the full six inches, with hollowed out coverings one inch of the outer wheel, all three discs are secured by fasteners. The axle 32 that attaches to the central disc 30 is supported by bearings (not shown) and driven by the DC motor 34. The central wheel assembly 28 is connected to the pancake motors 24, 26 on the top and bottom of the sphere 10, it is connected using bearings 36, 38 to allow torque spin to be applied to the central inertia wheel assembly 28. Attached to the pancake motors 24, 26 are the eight armatures 12a-h supporting the three (3) battery packs (see battery packs 14c, 16c, 18c, 14g, 16g, 18g) connected in series on each arm, wiring and voltage sensors. All eight arms 12a-h are connected electrically to support balanced operation of the DC motor 34. Turning now to FIG. 3, all armatures 12a-h are connected in parallel and connected to upper and lower DC buses 100, 102 observable as red and black wiring. The bottom two series battery packs on each arm (see battery packs 20c, 22c, 20g, 22g in FIG. 2) are spanned by a DC voltage meter (not shown). The eight armature sensor network battery packs 14, 16, 18, 20, 22 are connected in parallel as individual DC series strings (one on each of armatures 12a-h). The two (2) DC motors 104, 106 that power the central inertia wheel 30 during the experimental protocol are connected to the DC buses 100, 102 in a parallel configuration.

The external battery ring (i.e., battery rings 14, 16, 18, 20, 22) of the detector has two roles in the operation of the device. First as a power supply to keep the wheel 30 at high inertia when external grid power has been disconnected, the second is as a sensor array by means of the voltage sensors, and the experimental procedure to denote any unexpected or outside normal range of power draw (or voltage fluctuations) in the system. It is important to keep in mind that due to Kirchoff's Laws the absolute voltage measurements are imprecise due to unequal voltages connected to the same bus point of connection, and since batteries will charge and discharge differently the experiment requires detailed pre- and post-voltage measurements for each battery for each experiment.

### Protocol For Detector Operation Under Test

1. Align sensor array
2. Pretest of all battery voltages, noting position on armature and which armature A-H
3. Turn on voltage sensors and record Pre-test levels displayed on sensors
4. Turn on stopwatch
5. Engage DC drive motor/motors with external DC power supply
6. Record rotor voltage and current (power), rpms and motor temps every 30 seconds
7. At 4 min. (over 6000 rpm)—transition to DC batteries and record rpm/temp every 30 seconds
8. Continue to monitor rpm/motor temp—after 4 min. On battery power terminate motor power, record final spin time of central wheel assembly, turn off all equipment
9. Begin battery post experiment discharge measurements and recording, examine initial battery set measured to estimate rebound during read period, after final adjusted data view for outliers and min/max battery deltas, min/max arm deltas, correlate with Machina inertial reaction masses present

1. Utility patent for a field sensor and a process claim that are individually novel and combined novel.

2. The inventor claims to have developed a sensor array, consisting of rechargeable batteries and voltage sensors, that is able to simultaneously power a high-inertia, rotating device while interacting with the Mach-field (a novel inertial reaction field) postulated by E. Mach and articulated by A. Einstein.

3. The inventor has identified a novel electromagnetic interaction (with numerous documented experimental observations) which manifests when significant alterations to the high-inertial mass are attempted and the sensor arrays are in position to interact with the resulting novel field.
